(19) United States
(12) Patent Application Publication
(10) Pub. No.: US 2023/0178455 A1
(43) Pub. Date: Jun. 8, 2023

(54) SEMICONDUCTOR DEVICE AND POWER CONVERSION DEVICE

(71) Applicant: NIDEC CORPORATION, Kyoto (JP)

(72) Inventor: Ryo MAEDA, Kyoto (JP)

(21) Appl. No.: 18/060,569

(22) Filed: Dec. 1, 2022

(30) Foreign Application Priority Data
Dec. 3, 2021 (JP) 2021-197051

(51) Int. Cl. H01L 23/473; H01L 25/07; H01L 25/18; H01L 23/31

(52) U.S. Cl. CPC H01L 23/473; H01L 25/071; H01L 25/072; H01L 25/18; H01L 23/3107; H02P 27/06

(57) ABSTRACT

A semiconductor device includes a semiconductor element, a conductive member, a resin, and a cooling unit. The conductive member is joined to the semiconductor element. The resin seals a part of the semiconductor element and the conductive member. The cooling unit cools the conductive member inside the resin.

### CROSS-REFERENCE TO RELATED APPLICATIONS

The present invention claims priority under 35 U.S.C. § 119 to Japanese Patent Application No. 2021-197051 filed on Dec. 3, 2021, the entire content of which is incorporated herein by reference.

### FIELD OF THE INVENTION

The present disclosure relates to a semiconductor device and a power conversion device.

### BACKGROUND

There is known a semiconductor device including a semiconductor element such as an insulated gate bipolar transistor (IGBT). Such a semiconductor device is configured such that, for example, a semiconductor element is mounted on a circuit board, and the circuit board is bonded to a base plate.

A semiconductor element such as an IGBT generates a relatively large amount of heat during operation. In contrast to this, there has been proposed a semiconductor device in which a liquid cooling member is fixed to a base plate and a semiconductor element is cooled by a refrigerant in the cooling member.

It is desired to improve the cooling efficiency of a semiconductor element.

### SUMMARY

A semiconductor device according to one aspect of the present disclosure includes a semiconductor element, a conductive member joined to the semiconductor element, a resin that seals a part of the semiconductor element and the conductive member, and a cooling unit that cools the conductive member inside the resin.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a schematic diagram illustrating a longitudinal cross-section of a semiconductor device according to the first embodiment;

FIG. 2 is a schematic diagram illustrating a plane cross-section of the semiconductor device according to the first embodiment;

FIG. 3 is a schematic diagram illustrating a plane cross-section of a semiconductor device according to the first modification of the first embodiment;

FIG. 4 is a schematic diagram illustrating a longitudinal cross-section of a semiconductor device according to the second modification of the first embodiment;

FIG. 5 is a schematic diagram illustrating a longitudinal cross-section of a semiconductor device according to the second embodiment;

FIG. 6 is a schematic diagram illustrating a plane cross-section of the semiconductor device according to the second embodiment;

FIG. 7 is a schematic diagram illustrating a plane cross-section of a semiconductor device according to the first modification of the second embodiment;

FIG. 8 is a schematic diagram illustrating a longitudinal cross-section of a semiconductor device according to the second modification of the second embodiment;

FIG. 9 is a schematic diagram illustrating a longitudinal cross-section of a semiconductor device according to the third embodiment;

FIG. 10 is a schematic diagram illustrating a plane cross-section of the semiconductor device according to the third embodiment;

FIG. 11 is a schematic diagram illustrating a longitudinal cross-section of a semiconductor device according to a modification of the third embodiment;

FIG. 12 is a schematic diagram illustrating a plane cross-section of the semiconductor device according to the modification of the third embodiment;

FIG. 13 is a schematic diagram illustrating a longitudinal cross-section of a semiconductor device according to the fourth embodiment;

FIG. 14A is a schematic diagram illustrating a plane cross-section of the semiconductor device according to the fourth embodiment;

FIG. 14B is a schematic diagram illustrating a plane cross-section of the semiconductor device according to the fourth embodiment;

FIG. 14C is a schematic diagram illustrating a plane cross-section of the semiconductor device according to the fourth embodiment;

FIG. 15 is a schematic diagram illustrating a longitudinal cross-section of a semiconductor device according to the fifth embodiment;

FIG. 16 is a schematic diagram illustrating a longitudinal cross-section of a semiconductor device according to the sixth embodiment; and

FIG. 17 is a diagram illustrating the configuration of a motor system to which a semiconductor device is applied.

### DETAILED DESCRIPTION

Hereinafter, embodiments of a semiconductor device and a power conversion device disclosed in the present application will be described in detail with reference to the accompanying drawings. Note that the disclosed technology is not limited by the embodiments.

There is known a semiconductor device including a semiconductor element such as an insulated gate bipolar transistor (IGBT). Such a semiconductor device is configured such that, for example, a semiconductor element is mounted on a circuit board, and the circuit board is bonded to a base plate.

A semiconductor element such as an IGBT generates a relatively large amount of heat during operation. In contrast to this, there has been proposed a semiconductor device in which a liquid cooling member is fixed to a base plate and a semiconductor element is cooled by a refrigerant in the cooling member.

However, in the semiconductor device in which the liquid cooling member is fixed to the base plate, there is a problem that it is difficult to sufficiently cool the semiconductor element. That is, since the semiconductor device in which the liquid cooling member is fixed to the base plate has a structure in which the semiconductor element, the circuit board, the base plate, and the cooling member are stacked, a plurality of members positioned between the semiconductor element and the refrigerant in the cooling member may hinder heat transfer from the semiconductor element to the refrigerant. For example, a joining material that joins the semiconductor element and the circuit board, a circuit board, a joining material that joins the circuit board and the base plate, and the base plate are positioned between the semiconductor element and the refrigerant in the cooling member, so that heat transfer from the semiconductor element to the refrigerant is hindered. Since heat transfer from the semiconductor element to the refrigerant is hindered, heat generated in the semiconductor element is not sufficiently absorbed by the refrigerant, and as a result, the cooling efficiency of the semiconductor element may decrease.

Accordingly, it is desired to improve the cooling efficiency of the semiconductor element.

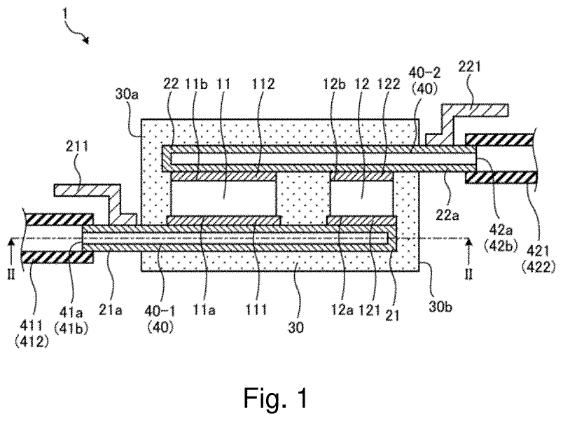

FIG. 1 is a schematic diagram illustrating a longitudinal cross-section of a semiconductor device 1 according to the first embodiment. As illustrated in FIG. 1, the semiconductor device 1 according to the first embodiment includes a semiconductor element 11, a diode 12, a first conductive member 21, and a second conductive member 22. The semiconductor element 11, the diode 12, a part of the first conductive member 21, and a part of the second conductive member 22 are covered with a sealing resin 30. As the sealing resin 30, for example, an insulating resin such as an epoxy resin can be used.

In the following description, one surface side of the semiconductor element 11 to which the first conductive member 21 is joined is defined as a lower side, and the other surface side of the semiconductor element 11 to which the second conductive member 22 is joined is defined as an upper side. However, the semiconductor device 1 may be used, for example, upside down, or may be used in an arbitrary posture.

The semiconductor element 11 is, for example, an IGBT. The diode 12 is, for example, a free wheeling diode (FWD). Note that the semiconductor element 11 may be a power metal oxide semiconductor field effect transistor (MOSFET), a gate turn-off (GTO) thyristor, or the like. Although the diode 12 and the semiconductor element 11 are distinguished from each other in this case, the diode 12 is also a type of semiconductor element.

The first conductive member 21 is a plate-like member made of a metal such as copper and is joined to the semiconductor element 11 and the diode 12. The first conductive member 21 is joined to a lower surface 11a of the semiconductor element 11 with a conductive joining material 111 and is joined to a lower surface 12a of the diode 12 with a conductive joining material 121. A part of the first conductive member 21 including a joint portion between the semiconductor element 11 and the diode 12 is sealed together with the semiconductor element 11 and the diode 12 with the sealing resin 30. The first conductive member 21 protrudes outward from one side surface 30a of the sealing resin 30 to form a protruding portion 21a. The protruding portion 21a is provided with an external connection terminal 211 that can be connected to, for example, wiring or an external component.

The second conductive member 22 is a plate-like member made of a metal such as copper and is joined to the semiconductor element 11 and the diode 12. The second conductive member 22 is joined to an upper surface 11b of the semiconductor element 11 with a conductive joining material 112 and is joined to an upper surface 12b of the diode 12 with a conductive joining material 122. A part of the second conductive member 22 including a joint portion between the semiconductor element 11 and the diode 12 is sealed together with the semiconductor element 11 and the diode 12 with the sealing resin 30. The second conductive member 22 protrudes outward from a side surface 30b opposite to the side surface 30a of the sealing resin 30 to form a protruding portion 22a. The protruding portion 22a is provided with an external connection terminal 221 that can be connected to, for example, wiring or an external component.

A refrigerant passage 40 through which an insulating refrigerant (to be also appropriately referred to as a “refrigerant” hereinafter) passes is provided inside each of the first conductive member 21 and the second conductive member 22. As the insulating refrigerant, for example, a fluorine-based inert liquid or an insulating liquid such as oil can be used from the viewpoint of suppressing the occurrence of a short circuit. Hereinafter, the refrigerant passage 40 provided inside the first conductive member 21 will be referred to as a “refrigerant passage 40-1”, and the refrigerant passage 40 provided inside the second conductive member 22 will be referred to as a “refrigerant passage 40-2”. When the refrigerant passage 40-1 and the refrigerant passage 40-2 are not distinguished, they are collectively referred to as the “refrigerant passage 40”. The refrigerant passage 40 is an example of a cooling unit. The first conductive member 21 is cooled by the refrigerant passing through the refrigerant passage 40-1, and the second conductive member 22 is cooled by the refrigerant passing through the refrigerant passage 40-2.

As described above, the first conductive member 21 and the second conductive member 22 are cooled by the refrigerant in the refrigerant passage 40, whereby the semiconductor element 11 and the diode 12 joined to the first conductive member 21 and the second conductive member 22 are cooled. In the semiconductor device 1, the number of members located between the semiconductor element 11 and the diode 12 and the refrigerant in the refrigerant passage 40 is smaller than that in a structure in which a semiconductor element, a circuit board, a base plate, and a cooling member are stacked. This promotes heat transfer from the semiconductor element 11 and the diode 12 to the refrigerant. Therefore, according to the first embodiment, since the heat generated in the semiconductor element 11 and the diode 12 can be smoothly absorbed by the refrigerant, the cooling efficiency of the semiconductor element 11 and the diode 12 can be improved. In addition, since a part of the first conductive member 21 and a part of the second conductive member 22 are covered with the sealing resin 30, it is possible to suppress the first conductive member 21 and the second conductive member 22 from being directly exposed to the external environment. Therefore, according to the first embodiment, when the heat generated in the semiconductor element 11 and the diode 12 is transferred to the refrigerant, the temperature rise of the refrigerant due to the external environment can be suppressed, so that the cooling efficiency of the semiconductor element 11 and the diode 12 can be improved.

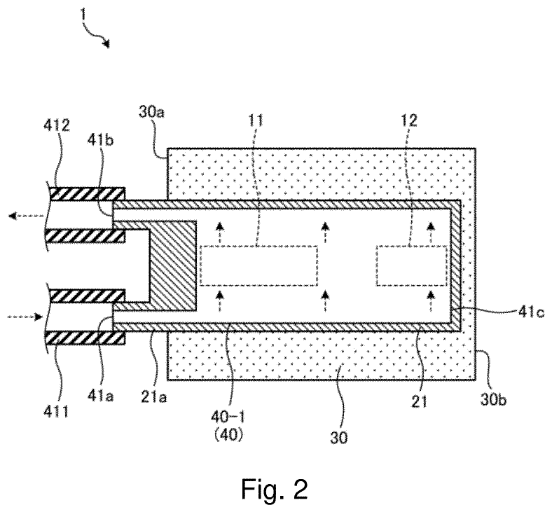

The configuration of the refrigerant passage 40-1 formed inside the first conductive member 21 will be described next with reference to FIG. 2. FIG. 2 is a schematic diagram illustrating a plane cross-section of the semiconductor device 1 according to the first embodiment. FIG. 2 illustrates a cross-section taken along line II-II in FIG. 1. Referring to FIG. 2, the flow of the refrigerant is indicated by the broken line arrows.

As shown in FIG. 2, the sealing resin 30 is formed in a quadrangular shape in plan view, and the first conductive member 21 has the protruding portion 21a protruding from one side surface 30a of the sealing resin 30.

The refrigerant passage 40-1 is formed in a U shape inside the first conductive member 21. Both openings 41a and 41b of the refrigerant passage 40-1 are disposed in the protruding portion 21a of the first conductive member 21. One opening 41a of the refrigerant passage 40-1 serves as an inlet into which the refrigerant flows, and the other opening 41b of the refrigerant passage 40-1 serves as an outlet from which the refrigerant flows out. Disposing both the openings 41a and 41b of the refrigerant passage 40-1 in the protruding portion 21a of the first conductive member 21 can concentrate the inlet and the outlet of the refrigerant on one side surface 30a side of the sealing resin 30 and downsize the semiconductor device 1.

An inlet pipe 411 made of an insulating material is connected to one opening 41a of the refrigerant passage 40-1. An outlet pipe 412 made of an insulating material is connected to the other opening 41b of the refrigerant passage 40-1. The inlet pipe 411 and the outlet pipe 412 are connected to a refrigerant circulation unit (not illustrated). The first conductive member 21 is cooled by circulating and supplying the refrigerant from the refrigerant circulation unit to the refrigerant passage 40-1 through the inlet pipe 411 and the outlet pipe 412.

In a region of the refrigerant passage 40-1 which overlaps the semiconductor element 11 and the diode 12 in plan view, a wide portion 41c having a width wider than other regions is formed. Forming the wide portion 41c in the refrigerant passage 40-1 can facilitate heat transfer from the semiconductor element 11 and the diode 12 to the refrigerant in the refrigerant passage 40-1. This makes it possible to further improve the cooling efficiency of the semiconductor element 11 and the diode 12.

The configuration of the refrigerant passage 40-2 formed inside the second conductive member 22 is basically similar to the configuration of the refrigerant passage 40-1. In the refrigerant passage 40-2, both openings 42a and 42b are disposed in the protruding portion 22a (see FIG. 1) of the second conductive member 22. Disposing both the openings 42a and 42b of the refrigerant passage 40-2 in the protruding portion 22a of the second conductive member 22 can concentrate the inlet and the outlet of the refrigerant on the side surface 30b side of the sealing resin 30 and downsize the semiconductor device 1.

An inlet pipe 421 (see FIG. 1) made of an insulating material is connected to one opening 42a of the refrigerant passage 40-2. An outlet pipe 422 (see FIG. 1) made of an insulating material is connected to the other opening 42b of the refrigerant passage 40-2. The inlet pipe 421 and the outlet pipe 422 are connected to a refrigerant circulation unit (not illustrated). The second conductive member 22 is cooled by circulating and supplying the refrigerant from the refrigerant circulation unit to the refrigerant passage 40-2 through the inlet pipe 421 and the outlet pipe 422.

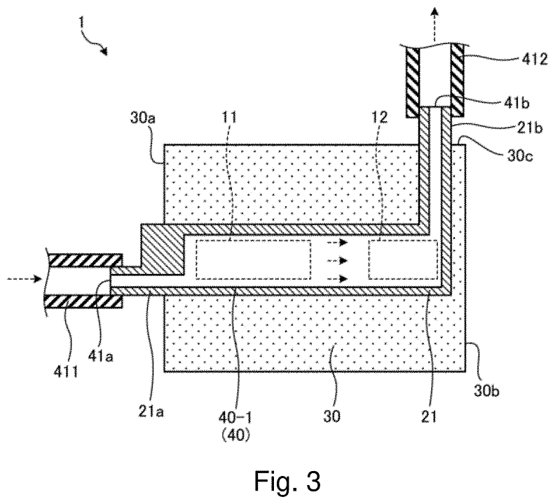

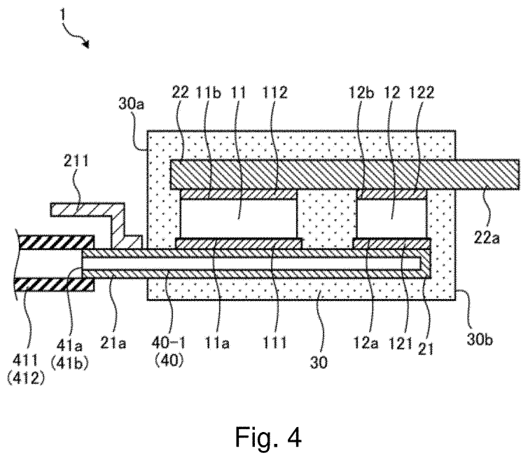

Various modifications of the semiconductor device 1 according to the first embodiment will be described next with reference to FIGS. 3 and 4. Note that, in various modifications described below, the same components as those of the first embodiment are denoted by the same reference numerals, and a redundant description may be omitted.

FIG. 3 is a schematic diagram illustrating a plane cross-section of a semiconductor device 1 according to the first modification of the first embodiment. FIG. 3 illustrates a cross-section taken along line II-II in FIG. 1. Referring to FIG. 3, the flow of the refrigerant is indicated by the broken line arrows. As shown in FIG. 3, in the first modification of the first embodiment, the first conductive member 21 has the protruding portion 21a protruding from one side surface 30a of the sealing resin 30, and a protruding portion 21b protruding from a side surface 30c adjacent to the side surface 30a of the sealing resin 30. The protruding portion 21a is an example of the first protruding portion, and the protruding portion 21b is an example of the second protruding portion.

The refrigerant passage 40-1 is formed in an L shape inside the first conductive member 21. One opening 41a of the refrigerant passage 40-1 is disposed in the protruding portion 21a of the first conductive member 21, and the other opening 41b of the refrigerant passage 40-1 is disposed in the protruding portion 21b of the first conductive member 21. One opening 41a of the refrigerant passage 40-1 serves as an inlet into which the refrigerant flows, and the other opening 41b of the refrigerant passage 40-1 serves as an outlet from which the refrigerant flows out. Disposing one opening 41a of the refrigerant passage 40-1 in the protruding portion 21a and disposing the other opening 41b in the protruding portion 21b will disperse the inlet and the outlet of the refrigerant to the side surface 30a and the side surface 30c of the sealing resin 30, thereby improving the degree of freedom of the circulation path of the refrigerant.

The configuration of the refrigerant passage 40-2 formed inside the second conductive member 22 may be similar to the configuration of the refrigerant passage 40-1 illustrated in FIG. 3.

The first modification has exemplified the case in which the protruding portion 21b of the first conductive member 21 protrudes from the side surface 30c adjacent to the side surface 30a of the sealing resin 30. However, the disclosed technology is not limited to this. For example, the protruding portion 21b of the first conductive member 21 may protrude from the side surface 30b opposite to the side surface 30a of the sealing resin 30. In such a case, the refrigerant passage 40-1 may be formed linearly inside the first conductive member 21 by arranging one opening 41a and the other opening 41b in the side surfaces facing each other.

FIG. 4 is a schematic diagram illustrating a longitudinal cross-section of a semiconductor device 1 according to the second modification of the first embodiment. As shown in FIG. 4, in the second modification of the first embodiment, the refrigerant passage 40 is provided inside one of the first conductive member 21 and the second conductive member 22. That is, the refrigerant passage 40-1 is provided inside the first conductive member 21, and the refrigerant passage 40-2 (see FIG. 1) is not provided inside the second conductive member 22.

As a result, in the second modification, the cooling efficiency of the semiconductor element 11 and the diode 12 can be improved with a simple configuration.

As shown in the second modification, the external connection terminal 221 (see FIG. 1) may not be provided on the protruding portion 22a of the second conductive member 22. That is, the protruding portion 22a of the second conductive member 22 may be used as an external connection terminal. As a result, in the second modification, since the number of components can be reduced, the semiconductor device 1 can be downsized.

The second embodiment relates to a variation of the cooling unit in the first embodiment.

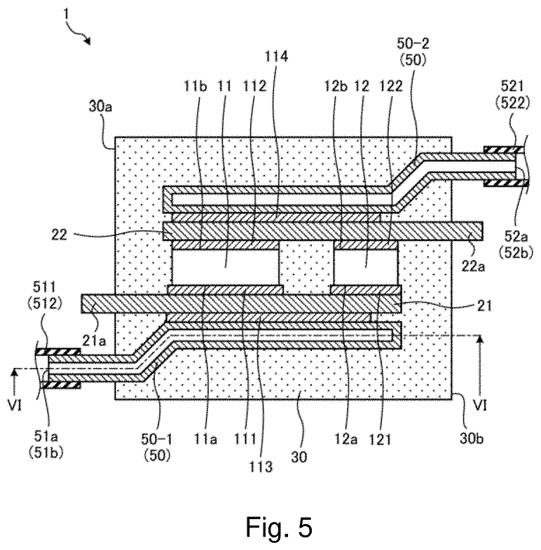

FIG. 5 is a schematic diagram illustrating a longitudinal cross-section of a semiconductor device 1 according to the second embodiment. As illustrated in FIG. 5, the semiconductor device 1 according to the second embodiment includes a semiconductor element 11, a diode 12, a first conductive member 21, and a second conductive member 22. The semiconductor element 11, the diode 12, a part of the first conductive member 21, and a part of the second conductive member 22 are covered with a sealing resin 30. As the sealing resin 30, for example, an insulating resin such as an epoxy resin can be used.

In the following description, one surface side of the semiconductor element 11 to which the first conductive member 21 is joined is defined as a lower side, and the other surface side of the semiconductor element 11 to which the second conductive member 22 is joined is defined as an upper side. However, the semiconductor device 1 may be used, for example, upside down, or may be used in an arbitrary posture.

The semiconductor element 11 is, for example, an IGBT. The diode 12 is, for example, an FWD. Note that the semiconductor element 11 may be a power MOSFET, a GTO thyristor, or the like. Although the diode 12 and the semiconductor element 11 are distinguished from each other in this case, the diode 12 is also a type of semiconductor element.

The first conductive member 21 is a plate-like member made of a metal such as copper and is joined to the semiconductor element 11 and the diode 12. The first conductive member 21 is joined to a lower surface 11a of the semiconductor element 11 with a conductive joining material 111 and is joined to a lower surface 12a of the diode 12 with a conductive joining material 121. A part of the first conductive member 21 including a joint portion between the semiconductor element 11 and the diode 12 is sealed together with the semiconductor element 11 and the diode 12 with the sealing resin 30. The first conductive member 21 protrudes outward from one side surface 30a of the sealing resin 30 to form a protruding portion 21a. The protruding portion 21a can be used as an external connection terminal that can be connected to, for example, wiring or an external component.

The second conductive member 22 is a plate-like member made of a metal such as copper and is joined to the semiconductor element 11 and the diode 12. The second conductive member 22 is joined to an upper surface 11b of the semiconductor element 11 with a conductive joining material 112 and is joined to an upper surface 12b of the diode 12 with a conductive joining material 122. A part of the second conductive member 22 including a joint portion between the semiconductor element 11 and the diode 12 is sealed together with the semiconductor element 11 and the diode 12 with the sealing resin 30. The second conductive member 22 protrudes outward from a side surface 30b opposite to the side surface 30a of the sealing resin 30 to form a protruding portion 22a. The protruding portion 22a can be used as an external connection terminal that can be connected to, for example, wiring or an external component.

A refrigerant pipe 50 through which an insulating refrigerant (to be also appropriately referred to as a “refrigerant” hereinafter) passes is provided for each of the first conductive member 21 and the second conductive member 22. As the insulating refrigerant, for example, a fluorine-based inert liquid or an insulating liquid such as oil can be used from the viewpoint of suppressing the occurrence of a short circuit. Hereinafter, the refrigerant pipe 50 provided in the first conductive member 21 is referred to as a “refrigerant pipe 50-1”, and the refrigerant pipe 50 provided in the second conductive member 22 is referred to as a “refrigerant pipe 50-2”. When the refrigerant pipe 50-1 and the refrigerant pipe 50-2 are not distinguished, they are collectively referred to as the “refrigerant pipe 50”. The refrigerant pipe 50 is an example of a cooling unit. The refrigerant pipe 50-1 is joined to the first conductive member 21 with a conductive joining material 113, and the refrigerant pipe 50-2 is joined to the second conductive member 22 with a conductive joining material 114. The first conductive member 21 is cooled by the refrigerant passing through the refrigerant pipe 50-1, and the second conductive member 22 is cooled by the refrigerant passing through the refrigerant pipe 50-2.

As described above, cooling the first conductive member 21 and the second conductive member 22 with the refrigerant in the refrigerant pipe 50 will cool the semiconductor element 11 and the diode 12 joined to the first conductive member 21 and the second conductive member 22. In the semiconductor device 1, the number of members located between the semiconductor element 11 and the diode 12 and the refrigerant in the refrigerant pipe 50 is smaller than that in a structure in which a semiconductor element, a circuit board, a base plate, and a cooling member are stacked. This promotes heat transfer from the semiconductor element 11 and the diode 12 to the refrigerant. Therefore, according to the second embodiment, since the heat generated in the semiconductor element 11 and the diode 12 can be smoothly absorbed by the refrigerant, the cooling efficiency of the semiconductor element 11 and the diode 12 can be improved. In addition, since a part of the first conductive member 21 and a part of the second conductive member 22 are covered with the sealing resin 30, it is possible to suppress the first conductive member 21 and the second conductive member 22 from being directly exposed to the external environment. Therefore, according to the second embodiment, when the heat generated in the semiconductor element 11 and the diode 12 is transferred to the refrigerant, the temperature rise of the refrigerant due to the external environment can be suppressed, so that the cooling efficiency of the semiconductor element 11 and the diode 12 can be improved.

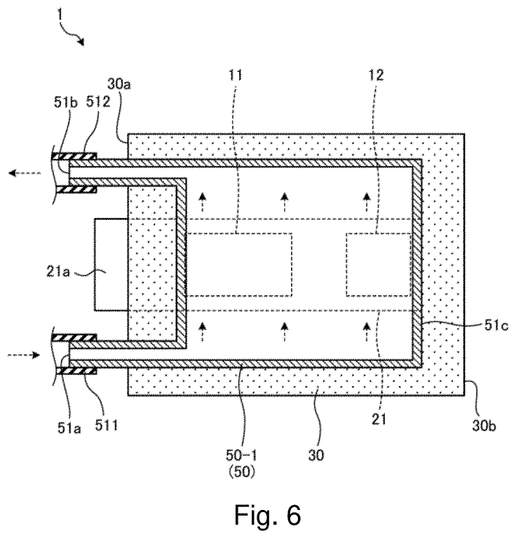

The configuration of the refrigerant pipe 50-1 joined to the first conductive member 21 will be described next with reference to FIG. 6. FIG. 6 is a schematic diagram illustrating a plane cross-section of the semiconductor device 1 according to the second embodiment. FIG. 6 illustrates a cross-section taken along line VI-VI in FIG. 5. Referring to FIG. 6, the flow of the refrigerant is indicated by the broken line arrows.

The refrigerant pipe 50-1 is formed in a U shape inside the sealing resin 30. Both end portions 51a and 51b of the refrigerant pipe 50-1 protrude from one side surface 30a of the sealing resin 30. Both end portions 51a of the refrigerant pipe 50-1 serve as inlets through which the refrigerant flows, and the other end portion 51b of the refrigerant pipe 50-1 serves as an outlet through which the refrigerant flows out. Since both the end portions 51a and 51b of the refrigerant pipe 50-1 protrude from one side surface 30a of the sealing resin 30, the inlet and the outlet of the refrigerant can be concentrated on the one side surface 30a side of the sealing resin 30, and the semiconductor device 1 can be downsized.

An inlet pipe 511 made of an insulating material is connected to one end portion 51a of the refrigerant pipe 50-1. An outlet pipe 512 made of an insulating material is connected to the other end portion 51b of the refrigerant pipe 50-1. The inlet pipe 511 and the outlet pipe 512 are connected to a refrigerant circulation unit (not illustrated). The first conductive member 21 is cooled by circulating and supplying the refrigerant from the refrigerant circulation unit to the refrigerant pipe 50-1 through the inlet pipe 511 and the outlet pipe 512.

In a region of the refrigerant pipe 50-1 which overlaps the semiconductor element 11 and the diode 12 in plan view, a wide portion 51c having a width wider than other regions is formed. Forming the wide portion 51c in the refrigerant pipe 50-1 can facilitate heat transfer from the semiconductor element 11 and the diode 12 to the refrigerant in the refrigerant pipe 50-1. This makes it possible to further improve the cooling efficiency of the semiconductor element 11 and the diode 12.

The configuration of the refrigerant pipe 50-2 joined to the second conductive member 22 is basically similar to the configuration of the refrigerant pipe 50-1. The refrigerant pipe 50-2 has both end portions 52a and 52b (see FIG. 5) protruding from the side surface 30b of the sealing resin 30. Since both the end portions 52a and 52b of the refrigerant pipe 50-2 protrude from the side surface 30b of the sealing resin 30, the inlet and the outlet of the refrigerant can be concentrated on the side surface 30b side of the sealing resin 30, and the semiconductor device 1 can be downsized.

An inlet pipe 521 (see FIG. 5) made of an insulating material is connected to one end portion 52a of the refrigerant pipe 50-2. An outlet pipe 522 (see FIG. 5) made of an insulating material is connected to the other end portion 52b of the refrigerant pipe 50-2. The inlet pipe 521 and the outlet pipe 522 are connected to a refrigerant circulation unit (not illustrated). The second conductive member 22 is cooled by circulating and supplying the refrigerant from the refrigerant circulation unit to the refrigerant pipe 50-2 through the inlet pipe 521 and the outlet pipe 522.

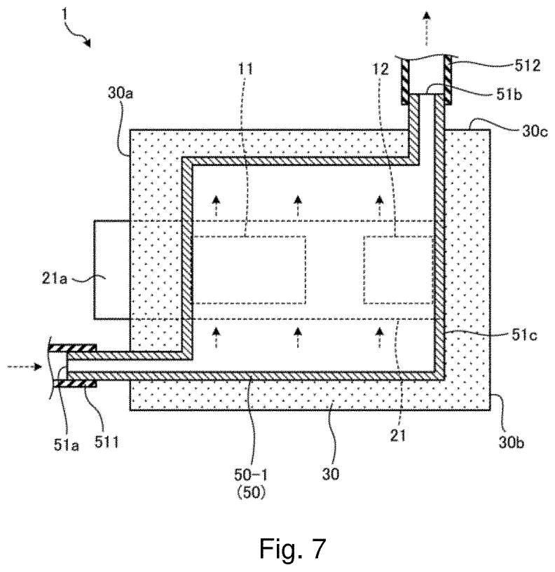

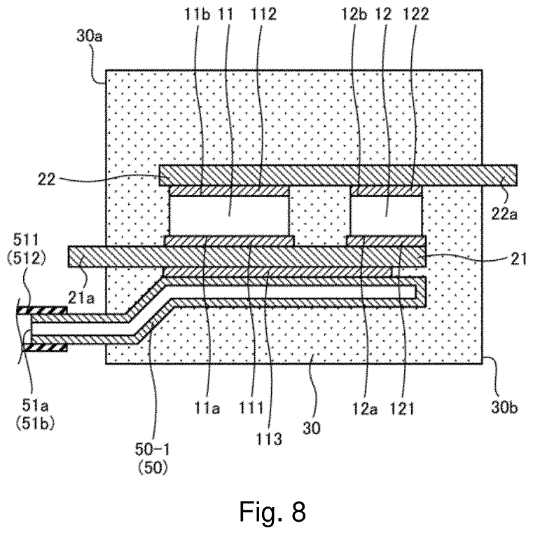

Various modifications of the semiconductor device 1 according to the second embodiment will be described next with reference to FIGS. 7 and 8. Note that, in various modifications described below, the same components as those of the first embodiment are denoted by the same reference numerals, and a redundant description may be omitted.

FIG. 7 is a schematic diagram illustrating a plane cross-section of a semiconductor device 1 according to the second modification of the first embodiment. FIG. 7 illustrates a cross-section taken along line VI-VI in FIG. 5. Referring to FIG. 7, the flow of the refrigerant is indicated by the broken line arrows. As shown in FIG. 7, in the first modification of the second embodiment, the refrigerant pipe 50-1 is formed in an L shape inside the sealing resin 30. One end portion 51a of the refrigerant pipe 50-1 protrudes from one side surface 30a of the sealing resin 30, and the other end portion 51b of the refrigerant pipe 50-1 protrudes from the side surface 30c adjacent to the side surface 30a of the sealing resin 30. One end portion 51a of the refrigerant pipe 50-1 serve as inlets through which the refrigerant flows, and the other end portion 51b of the refrigerant pipe 50-1 serves as an outlet through which the refrigerant flows out.

As described above, in the first modification, one end portion 51a of the refrigerant pipe 50-1 protrudes from the side surface 30a of the sealing resin 30, and the other end portion 51b of the refrigerant pipe 50-1 protrudes from the side surface 30c of the sealing resin 30, whereby the degree of freedom of the circulation path of the refrigerant can be improved.

The configuration of the refrigerant pipe 50-2 joined to the second conductive member 22 may be similar to the configuration of the refrigerant pipe 50-1 illustrated in FIG. 7.

The first modification has exemplified the case where the other end portion 51b of the refrigerant pipe 50-1 protrudes from the side surface 30c adjacent to the side surface 30a of the sealing resin 30. However, the disclosed technology is not limited to this. For example, the other end portion 51b of the refrigerant pipe 50-1 may protrude from the side surface 30b opposite to the side surface 30a of the sealing resin 30. In such a case, the refrigerant pipe 50-1 may be formed linearly inside the sealing resin 30.

FIG. 8 is a schematic diagram illustrating a longitudinal cross-section of a semiconductor device 1 according to the second modification of the second embodiment. As shown in FIG. 8, in the second modification of the second embodiment, the refrigerant pipe 50 is provided for one of the first conductive member 21 and the second conductive member 22. That is, the refrigerant pipe 50-1 is joined to the first conductive member 21 through the conductive joining material 113, and the refrigerant pipe 50-2 (see FIG. 5) is not joined to the second conductive member 22.

As a result, in the second modification, the cooling efficiency of the semiconductor element 11 and the diode 12 can be improved with a simple configuration.

The third embodiment relates to a variation of the cooling unit in the first embodiment.

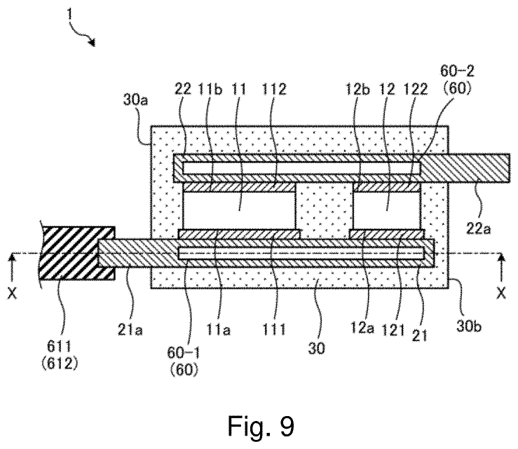

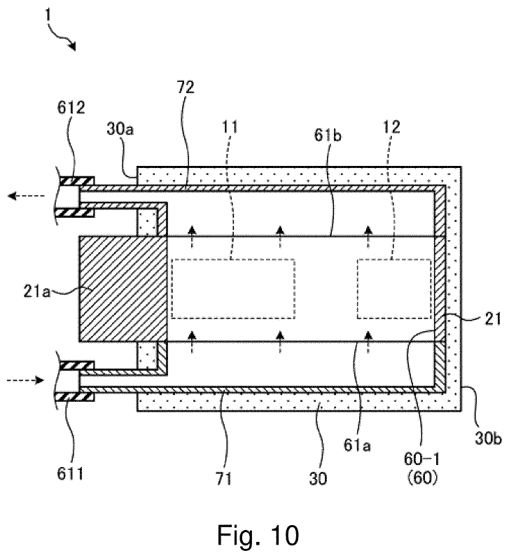

FIG. 9 is a schematic diagram illustrating a longitudinal cross-section of a semiconductor device 1 according to the third embodiment. FIG. 10 is a schematic diagram illustrating a plane cross-section of the semiconductor device 1 according to the third embodiment. FIG. 10 illustrates a cross-section taken along line X-X in FIG. 9. Referring to FIG. 10, the flow of the refrigerant is indicated by the broken line arrows.

As illustrated in FIGS. 9 and 10, the semiconductor device 1 according to the third embodiment includes a semiconductor element 11, a diode 12, a first conductive member 21, and a second conductive member 22. The semiconductor element 11, the diode 12, a part of the first conductive member 21, and a part of the second conductive member 22 are covered with a sealing resin 30. As the sealing resin 30, for example, an insulating resin such as an epoxy resin can be used.

In the following description, one surface side of the semiconductor element 11 to which the first conductive member 21 is joined is defined as a lower side, and the other surface side of the semiconductor element 11 to which the second conductive member 22 is joined is defined as an upper side. However, the semiconductor device 1 may be used, for example, upside down, or may be used in an arbitrary posture.

The semiconductor element 11 is, for example, an IGBT. The diode 12 is, for example, an FWD. Note that the semiconductor element 11 may be a power MOSFET, a GTO thyristor, or the like. Although the diode 12 and the semiconductor element 11 are distinguished from each other in this case, the diode 12 is also a type of semiconductor element.

The first conductive member 21 is a plate-like member made of a metal such as copper and is joined to the semiconductor element 11 and the diode 12. The first conductive member 21 is joined to a lower surface 11a of the semiconductor element 11 with a conductive joining material 111 and is joined to a lower surface 12a of the diode 12 with a conductive joining material 121. A part of the first conductive member 21 including a joint portion between the semiconductor element 11 and the diode 12 is sealed together with the semiconductor element 11 and the diode 12 with the sealing resin 30. The first conductive member 21 protrudes outward from one side surface 30a 0of the sealing resin 30 to form a protruding portion 21a. The protruding portion 21a can be used as an external connection terminal that can be connected to, for example, wiring or an external component.

The second conductive member 22 is a plate-like member made of a metal such as copper and is joined to the semiconductor element 11 and the diode 12. The second conductive member 22 is joined to an upper surface 11b of the semiconductor element 11 with a conductive joining material 112 and is joined to an upper surface 12b of the diode 12 with a conductive joining material 122. A part of the second conductive member 22 including a joint portion between the semiconductor element 11 and the diode 12 is sealed together with the semiconductor element 11 and the diode 12 with the sealing resin 30. The second conductive member 22 protrudes outward from a side surface 30b opposite to the side surface 30a of the sealing resin 30 to form a protruding portion 22a. The protruding portion 22a can be used as an external connection terminal that can be connected to, for example, wiring or an external component.

A through-hole 60 extending in the width direction of the first conductive member 21 is provided in a region overlapping the semiconductor element 11 and the diode 12 in plan view of each of the first conductive member 21 and the second conductive member 22. Hereinafter, the through-hole 60 provided in the first conductive member 21 is referred to as a “through-hole 60-1”, and the through-hole 60 provided in the second conductive member 22 is referred to as a “through-hole 60-2”. In addition, when the through-hole 60-1 and the through-hole 60-2 are not distinguished, they are collectively referred to as the “through-hole 60”.

One opening 61a of the through-hole 60-1 serves as an inlet into which the refrigerant flows, and the other opening 61b of the through-hole 60-1 serves as an outlet from which the refrigerant flows out. A refrigerant supply pipe 71 that supplies an insulating refrigerant (to be also appropriately referred to as a “refrigerant” hereinafter) to one opening 61a of the through-hole 60-1 is connected to one opening 61a of the through-hole 60-1. One opening 61a of the through-hole 60-1 is connected to the refrigerant supply pipe 71 by a known method such as solder joining, sintering, or laser processing. A refrigerant discharge pipe 72 for discharging the insulating refrigerant from the other opening 61b of the through-hole 60-1 is connected to the other opening 61b of the through-hole 60-1. One opening 61b of the through-hole 60-1 is connected to the refrigerant discharge pipe 72 by a known method such as solder joining, sintering, or laser processing.

The refrigerant supply pipe 71 and the refrigerant discharge pipe 72 protrude from one side surface 30a of the sealing resin 30. The refrigerant supply pipe 71 is connected to an inlet pipe 611 formed of an insulating material, and the refrigerant discharge pipe 72 is connected to an outlet pipe 612 formed of an insulating material. The inlet pipe 611 and the outlet pipe 612 are connected to a refrigerant circulation unit (not illustrated). The first conductive member 21 is cooled by circulating and supplying the refrigerant from the refrigerant circulation unit to the through-hole 60-1 through the inlet pipe 611, the refrigerant supply pipe 71, the refrigerant discharge pipe 72, and the outlet pipe 612. The refrigerant supply pipe 71 and the refrigerant discharge pipe 72 are examples of a cooling unit.

The configuration of the through-hole 60-2 provided in the second conductive member 22 is basically similar to the configuration of the through-hole 60-1. Similarly to the through-hole 60-1, a refrigerant supply pipe and a refrigerant discharge pipe are connected to the through-hole 60-2, and the refrigerant supply pipe and the refrigerant discharge pipe are finally connected to the refrigerant circulation unit through an inlet pipe and an outlet pipe formed of an insulating material. The second conductive member 22 is cooled by circulating and supplying the refrigerant from the refrigerant circulation unit to the through-hole 60-2.

As described above, cooling the first conductive member 21 and the second conductive member 22 with the refrigerant in the through-hole 60 will cool the semiconductor element 11 and the diode 12 joined to the first conductive member 21 and the second conductive member 22. In the semiconductor device 1, the number of members located between the semiconductor element 11 and the diode 12 and the refrigerant in the through-hole 60 is smaller than that in a structure in which a semiconductor element, a circuit board, a base plate, and a cooling member are stacked. This promotes heat transfer from the semiconductor element 11 and the diode 12 to the refrigerant. Therefore, according to the third embodiment, since the heat generated in the semiconductor element 11 and the diode 12 can be smoothly absorbed by the refrigerant, the cooling efficiency of the semiconductor element 11 and the diode 12 can be improved. In addition, since a part of the first conductive member 21 and a part of the second conductive member 22 are covered with the sealing resin 30, it is possible to suppress the first conductive member 21 and the second conductive member 22 from being directly exposed to the external environment. Therefore, according to the third embodiment, when the heat generated in the semiconductor element 11 and the diode 12 is transferred to the refrigerant, the temperature rise of the refrigerant due to the external environment can be suppressed, so that the cooling efficiency of the semiconductor element 11 and the diode 12 can be improved.

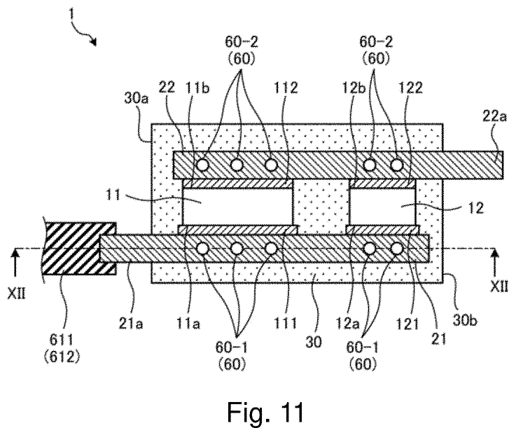

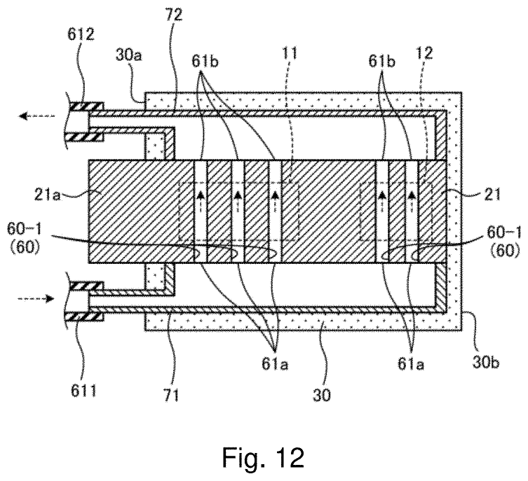

Various modifications of the semiconductor device 1 according to a modification of the third embodiment will be described next with reference to FIGS. 11 and 12. Note that, in the modification described below, the same components as those of the third embodiment are denoted by the same reference numerals, and a redundant description may be omitted.

FIG. 11 is a schematic diagram illustrating a longitudinal cross-section of a semiconductor device 1 according to a modification of the third embodiment. FIG. 12 is a schematic diagram illustrating a plane cross-section of a semiconductor device 1 according to the modification of the third embodiment. FIG. 12 illustrates a cross-section taken along line XII-XII in FIG. 11. Referring to FIG. 12, the flow of the refrigerant is indicated by the broken line arrows.

As shown in FIGS. 11 and 12, in the modification of the third embodiment, a plurality of through-holes 60 are provided in each of the first conductive member 21 and the second conductive member 22. In this case, since the configuration of the plurality of through-holes 60-2 provided in the second conductive member 22 is similar to the configuration of the plurality of through-holes 60-1 provided in the first conductive member 21, a description thereof will be omitted. The refrigerant supply pipe 71 supplies an insulating refrigerant (to be also appropriately referred to as a “refrigerant” hereinafter) to one opening 61a of each through-hole 60-1. The refrigerant discharge pipe 72 discharges the insulating refrigerant from the other opening 61b of each through-hole 60-1. This allows the refrigerant supply pipe 71 and the refrigerant discharge pipe 72 to circulate the refrigerant through the plurality of through-holes 60.

As a result, in the modification, the contact area between the first conductive member 21 and the refrigerant can be increased as compared with the case where one through-hole 60 is provided in the first conductive member 21, so that the cooling efficiency of the semiconductor element 11 and the diode 12 can be further improved.

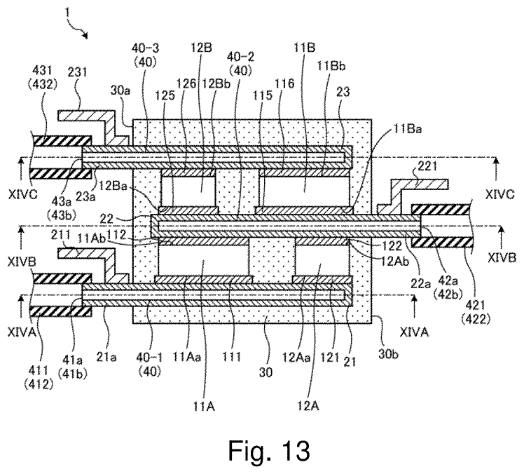

FIG. 13 is a schematic diagram illustrating a longitudinal cross-section of a semiconductor device 1 according to the fourth embodiment. As illustrated in FIG. 13, the semiconductor device 1 according to the fourth embodiment is a so-called 2 in 1 semiconductor module. The semiconductor device 1 includes a first semiconductor element 11A, a first diode 12A, a second semiconductor element 11B, and a second diode 12B. The semiconductor device 1 includes a first conductive member 21, a second conductive member 22, and a third conductive member 23. The first semiconductor element 11A, the first diode 12A, the second semiconductor element 11B, the second diode 12B, a part of the first conductive member 21, a part of the second conductive member 22, and a part of the third conductive member 23 are covered with a sealing resin 30. As the sealing resin 30, for example, an insulating resin such as an epoxy resin can be used.

In the following description, one surface side of the first semiconductor element 11A to which the first conductive member 21 is joined is defined as a lower side, and the other surface side of the first semiconductor element 11A to which the second conductive member 22 is joined is defined as an upper side. However, the semiconductor device 1 may be used, for example, upside down, or may be used in an arbitrary posture.

The first semiconductor element 11A and the second semiconductor element 11B are, for example, IGBTs. The first diode 12A and the second diode 12B are, for example, FWD. The combination of the first semiconductor element 11A and the first diode 12A and the combination of the second semiconductor element 11B and the second diode 12B are arranged at intervals in the vertical direction inside the sealing resin 30. Note that the first semiconductor element 11A and the second semiconductor element 11B may be power MOSFETs, GTO thyristors, or the like. Although the first diode 12A and the first semiconductor element 11A are distinguished here, the first diode 12A is also a type of semiconductor element. Although the second diode 12B and the second semiconductor element 11B are distinguished from each other, the second diode 12B is also a type of semiconductor element.

The first conductive member 21 is a plate-like member made of a metal such as copper and is joined to the first semiconductor element 11A and the first diode 12A. The first conductive member 21 is joined to a lower surface 11Aa of the first semiconductor element 11A with a conductive joining material 111 and is joined to a lower surface 12Aa of the first diode 12A with a conductive joining material 121. A part of the first conductive member 21 including a joint portion between the first semiconductor element 11A and the first diode 12A is sealed together with the first semiconductor element 11A and the first diode 12A with the sealing resin 30. The first conductive member 21 protrudes outward from one side surface 30a of the sealing resin 30 to form a protruding portion 21a. The protruding portion 21a is provided with an external connection terminal 211 that can be connected to, for example, wiring or an external component.

The second conductive member 22 is a plate-like member made of a metal such as copper and is joined to the first semiconductor element 11A, the first diode 12A, the second semiconductor element 11B, and the second diode 12B. The second conductive member 22 is joined to an upper surface 11Ab of the first semiconductor element 11A with a conductive joining material 112 and is joined to the upper surface 12Ab of the first diode 12A with a conductive joining material 122. The second conductive member 22 is joined to a lower surface 11Ba of the second semiconductor element 11B with a conductive joining material 115 and is joined to a lower surface 12Ba of the second diode 12B with a conductive joining material 125. The first semiconductor element 11A, the first diode 12A, and a part of the second conductive member 22 which includes a joint portion between the second semiconductor element 11B and the second diode 12B are sealed with a sealing resin 30, together with the first semiconductor element 11A, the first diode 12A, the second semiconductor element 11B, and the second diode 12B. The second conductive member 22 protrudes outward from a side surface 30b opposite to the side surface 30a of the sealing resin 30 to form a protruding portion 22a. The protruding portion 22a is provided with an external connection terminal 221 that can be connected to, for example, wiring or an external component.

The third conductive member 23 is a plate-like member made of metal such as copper and is joined to the second semiconductor element 11B and the second diode 12B. The third conductive member 23 is joined to the upper surface 11Bb of the second semiconductor element 11B with a conductive joining material 116 and is joined to an upper surface 12Bb of the second diode 12B with a conductive joining material 126. A part of the third conductive member 23 which includes a joint portion between the second semiconductor element 11B and the second diode 12B is sealed with the sealing resin 30, together with the second semiconductor element 11B and the second diode 12B. The third conductive member 23 protrudes outward from the side surface 30a of the sealing resin 30 to form a protruding portion 23a. The protruding portion 23a is provided with an external connection terminal 231 that can be connected to, for example, wiring or an external component.

A refrigerant passage 40 through which an insulating refrigerant (to be also appropriately referred to as the “refrigerant” hereinafter) passes is provided inside each of the first conductive member 21, the second conductive member 22, and the third conductive member 23. As the insulating refrigerant, for example, a fluorine-based inert liquid or an insulating liquid such as oil can be used. Hereinafter, the refrigerant passage 40 provided inside the first conductive member 21 will be referred to as a “refrigerant passage 40-1”, the refrigerant passage 40 provided inside the second conductive member 22 will be referred to as a “refrigerant passage 40-2”, and the refrigerant passage 40 provided inside the third conductive member 23 will be referred to as a “refrigerant passage 40-3”. When the refrigerant passage 40-1, the refrigerant passage 40-2, and the refrigerant passage 40-3 are not distinguished, they are collectively referred to as the “refrigerant passage 40”. The refrigerant passage 40 is an example of a cooling unit. The first conductive member 21 is cooled by the refrigerant passing through the refrigerant passage 40-1, the second conductive member 22 is cooled by the refrigerant passing through the refrigerant passage 40-2, and the third conductive member 23 is cooled by the refrigerant passing through the refrigerant passage 40-3.

As described above, cooling the first conductive member 21 and the second conductive member 22 with the refrigerant in the refrigerant passage 40 will cool the first semiconductor element 11A and the first diode 12A joined to the first conductive member 21 and the second conductive member 22. Cooling the second conductive member 22 and the third conductive member 23 with the refrigerant in the refrigerant passage 40 will cool the second semiconductor element 11B and the second diode 12B joined to the second conductive member 22 and the third conductive member 23. In the semiconductor device 1, the number of members located between the first semiconductor element 11A (second semiconductor element 11B) and the first diode 12A (second diode 12B) and the refrigerant in the refrigerant passage 40 is smaller than that in a structure in which a semiconductor element, a circuit board, a base plate, and a cooling member are stacked. This promotes heat transfer from the first semiconductor element 11A, the first diode 12A, the second semiconductor element 11B, and the second diode 12B to the refrigerant. Therefore, according to the fourth embodiment, the heat generated in the first semiconductor element 11A, the first diode 12A, the second semiconductor element 11B, and the second diode 12B can be smoothly absorbed into the refrigerant. As a result, according to the fourth embodiment, the cooling efficiency of the first semiconductor element 11A, the first diode 12A, the second semiconductor element 11B, and the second diode 12B can be improved. In addition, since a part of the first conductive member 21, a part of the second conductive member 22, and a part of the third conductive member 23 are covered with the sealing resin 30, it is possible to suppress the first conductive member 21, the second conductive member 22, and the third conductive member 23 from being directly exposed to the external environment. Therefore, according to the fourth embodiment, when the heat generated in the first semiconductor element 11A, the first diode 12A, the second semiconductor element 11B, and the second diode 12B is transferred to the refrigerant, a temperature rise of the refrigerant due to the external environment can be suppressed. As a result, according to the fourth embodiment, in the 2 in 1 semiconductor module, the cooling efficiency of the first semiconductor element 11A, the first diode 12A, the second semiconductor element 11B, and the second diode 12B can be improved.

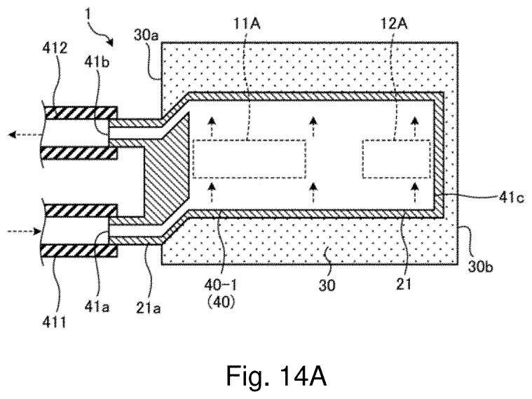

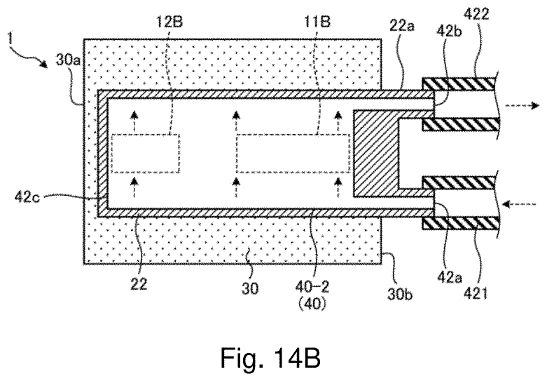

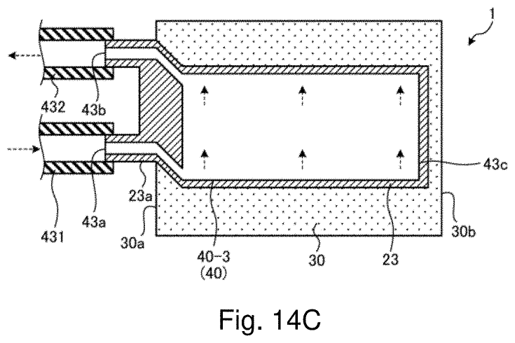

The configuration of the refrigerant passage 40 (refrigerant passages 40-1 to 40-3) formed inside each of the first conductive member 21, the second conductive member 22, and the third conductive member 23 will be described next with reference to FIG. 14. FIGS. 14A to 14C are schematic diagrams each illustrating a plane cross-section of the semiconductor device 1 according to the fourth embodiment. FIG. 14A illustrates a cross-section taken along line XIVA-XIVA in FIG. 13. FIG. 14B illustrates a cross-section taken along line XIVB-XIVB in FIG. 13. FIG. 14C illustrates a cross-section taken along line XIVC-XIVC in FIG. 13. Referring to FIGS. 14A to 14C, the flow of the refrigerant is indicated by the broken line arrows. As described above, the first conductive member 21 has the protruding portion 21a protruding from one side surface 30a of the sealing resin 30. The second conductive member 22 has the protruding portion 22a protruding from the side surface 30b opposite to the side surface 30a of the sealing resin 30. The third conductive member 23 has the protruding portion 23a protruding from one side surface 30a of the sealing resin 30.

As illustrated in FIG. 14A, the refrigerant passage 40-1 is formed in a U shape inside the first conductive member 21. Both openings 41a and 41b of the refrigerant passage 40-1 are disposed in the protruding portion 21a of the first conductive member 21. One opening 41a of the refrigerant passage 40-1 serves as an inlet into which the refrigerant flows, and the other opening 41b of the refrigerant passage 40-1 serves as an outlet from which the refrigerant flows out. Disposing both the openings 41a and 41b of the refrigerant passage 40-1 in the protruding portion 21a of the first conductive member 21 can concentrate the inlet and the outlet of the refrigerant on one side surface 30a side of the sealing resin 30 and downsize the semiconductor device 1.

An inlet pipe 411 made of an insulating material is connected to one opening 41a of the refrigerant passage 40-1. An outlet pipe 412 made of an insulating material is connected to the other opening 41b of the refrigerant passage 40-1. The inlet pipe 411 and the outlet pipe 412 are connected to a refrigerant circulation unit (not illustrated). The first conductive member 21 is cooled by circulating and supplying the refrigerant from the refrigerant circulation unit to the refrigerant passage 40-1 through the inlet pipe 411 and the outlet pipe 412.

In a region of the refrigerant passage 40-1 which overlaps the first semiconductor element 11A and the first diode 12A in plan view, a wide portion 41c having a width wider than other regions is formed. Forming the wide portion 41c in the refrigerant passage 40-1 can facilitate heat transfer from the first semiconductor element 11A and the first diode 12A to the refrigerant in the refrigerant passage 40-1. This makes it possible to further improve the cooling efficiency of the first semiconductor element 11A and the first diode 12A.

As illustrated in FIG. 14B, the refrigerant passage 40-2 is formed in a U shape inside the second conductive member 22. Both openings 42a and 42b of the refrigerant passage 40-2 are disposed in the protruding portion 22a of the second conductive member 22. One opening 42a of the refrigerant passage 40-2 serves as an inlet into which the refrigerant flows, and the other opening 42b of the refrigerant passage 40-2 serves as an outlet from which the refrigerant flows out. Disposing both the openings 42a and 42b of the refrigerant passage 40-2 in the protruding portion 22a of the second conductive member 22 can concentrate the inlet and the outlet of the refrigerant on one side surface 30b side of the sealing resin 30 and downsize the semiconductor device 1.

An inlet pipe 421 made of an insulating material is connected to one opening 42a of the refrigerant passage 40-2. An outlet pipe 422 made of an insulating material is connected to the other opening 42b of the refrigerant passage 40-2. The inlet pipe 421 and the outlet pipe 422 are connected to a refrigerant circulation unit (not illustrated). The second conductive member 22 is cooled by circulating and supplying the refrigerant from the refrigerant circulation unit to the refrigerant passage 40-2 through the inlet pipe 421 and the outlet pipe 422.

In a region overlapping the first semiconductor element 11A, the first diode 12A, the second semiconductor element 11B, and the second diode 12B in plan view of the refrigerant passage 40-2, a wide portion 42c having a width wider than other regions is formed. Forming the wide portion 42c in the refrigerant passage 40-2 can smooth heat transfer from the first semiconductor element 11A, the first diode 12A, the second semiconductor element 11B, and the second diode 12B to the refrigerant in the refrigerant passage 40-2. This makes it possible to improve the cooling efficiency of the first semiconductor element 11A, the first diode 12A, the second semiconductor element 11B, and the second diode 12B.

As illustrated in FIG. 14C, the refrigerant passage 40-3 is formed in a U shape inside the third conductive member 23. Both openings 43a and 43b of the refrigerant passage 40-3 are disposed in the protruding portion 23a of the third conductive member 23. One opening 43a of the refrigerant passage 40-3 serves as an inlet into which the refrigerant flows, and the other opening 43b of the refrigerant passage 40-3 serves as an outlet from which the refrigerant flows out. Disposing both the openings 43a and 43b of the refrigerant passage 40-3 in the protruding portion 23a of the third conductive member 23 can concentrate the inlet and the outlet of the refrigerant on one side surface 30a side of the sealing resin 30 and downsize the semiconductor device 1.

An inlet pipe 431 made of an insulating material is connected to one opening 43a of the refrigerant passage 40-3. An outlet pipe 432 made of an insulating material is connected to the other opening 43b of the refrigerant passage 40-3. The inlet pipe 431 and the outlet pipe 432 are connected to a refrigerant circulation unit (not illustrated). The third conductive member 23 is cooled by circulating and supplying the refrigerant from the refrigerant circulation unit to the refrigerant passage 40-3 through the inlet pipe 431 and the outlet pipe 432.

In a region of the refrigerant passage 40-3 which overlaps the second semiconductor element 11B and the second diode 12B in plan view, a wide portion 43c having a width wider than other regions is formed. Forming the wide portion 43c in the refrigerant passage 40-3 can facilitate heat transfer from the second semiconductor element 11B and the second diode 12B to the refrigerant in the refrigerant passage 40-3. This makes it possible to further improve the cooling efficiency of the second semiconductor element 11B and the second diode 12B.

As illustrated in FIGS. 14A to 14C, the protruding portions 21a to 23a in which the inlet and the outlet of refrigerant passage 40 are disposed are disposed at positions shifted from each other in plan view. This can improve workability when pipes such as the inlet pipe 411 and the outlet pipe 412 are connected to the inlet and the outlet of the refrigerant passage 40.

The fifth embodiment relates to a variation of the cooling unit in the fourth embodiment.

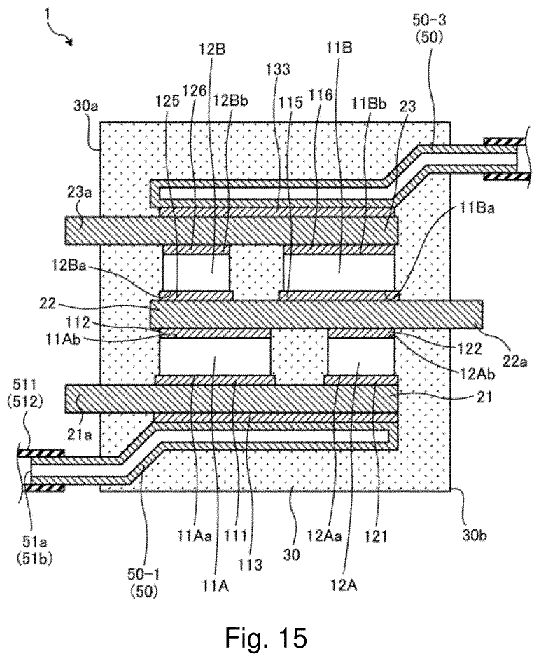

FIG. 15 is a schematic diagram illustrating a longitudinal cross-section of a semiconductor device 1 according to the fifth embodiment. As illustrated in FIG. 15, the semiconductor device 1 according to the fifth embodiment is a so-called 2 in 1 semiconductor module. The semiconductor device 1 includes a first semiconductor element 11A, a first diode 12A, a second semiconductor element 11B, and a second diode 12B. The semiconductor device 1 includes a first conductive member 21, a second conductive member 22, and a third conductive member 23. The first semiconductor element 11A, the first diode 12A, the second semiconductor element 11B, the second diode 12B, a part of the first conductive member 21, a part of the second conductive member 22, and a part of the third conductive member 23 are covered with a sealing resin 30. As the sealing resin 30, for example, an insulating resin such as an epoxy resin can be used.

In the following description, one surface side of the first semiconductor element 11A to which the first conductive member 21 is joined is defined as a lower side, and the other surface side of the first semiconductor element 11A to which the second conductive member 22 is joined is defined as an upper side. However, the semiconductor device 1 may be used, for example, upside down, or may be used in an arbitrary posture.

The first semiconductor element 11A and the second semiconductor element 11B are, for example, IGBTs. The first diode 12A and the second diode 12B are, for example, FWD. The combination of the first semiconductor element 11A and the first diode 12A and the combination of the second semiconductor element 11B and the second diode 12B are arranged at intervals in the vertical direction inside the sealing resin 30. Note that the first semiconductor element 11A and the second semiconductor element 11B may be power MOSFETs, GTO thyristors, or the like. Although the first diode 12A and the first semiconductor element 11A are distinguished here, the first diode 12A is also a type of semiconductor element. Although the second diode 12B and the second semiconductor element 11B are distinguished from each other, the second diode 12B is also a type of semiconductor element.

The first conductive member 21 is a plate-like member made of a metal such as copper and is joined to the first semiconductor element 11A and the first diode 12A. The first conductive member 21 is joined to a lower surface 11Aa of the first semiconductor element 11A with a conductive joining material 111 and is joined to a lower surface 12Aa of the first diode 12A with a conductive joining material 121. A part of the first conductive member 21 including a joint portion between the first semiconductor element 11A and the first diode 12A is sealed together with the first semiconductor element 11A and the first diode 12A with the sealing resin 30. The first conductive member 21 protrudes outward from one side surface 30a of the sealing resin 30 to form a protruding portion 21a. The protruding portion 21a can be used as an external connection terminal that can be connected to, for example, wiring or an external connection terminal 211.

The second conductive member 22 is a plate-like member made of a metal such as copper and is joined to the first semiconductor element 11A, the first diode 12A, the second semiconductor element 11B, and the second diode 12B. The second conductive member 22 is joined to an upper surface 11Ab of the first semiconductor element 11A with a conductive joining material 112 and is joined to the upper surface 12Ab of the first diode 12A with a conductive joining material 122. The second conductive member 22 is joined to a lower surface 11Ba of the second semiconductor element 11B with a conductive joining material 115 and is joined to a lower surface 12Ba of the second diode 12B with a conductive joining material 125. The first semiconductor element 11A, the first diode 12A, and a part of the second conductive member 22 which includes a joint portion between the second semiconductor element 11B and the second diode 12B are sealed with a sealing resin 30, together with the first semiconductor element 11A, the first diode 12A, the second semiconductor element 11B, and the second diode 12B. The second conductive member 22 protrudes outward from a side surface 30b opposite to the side surface 30a of the sealing resin 30 to form a protruding portion 22a. The protruding portion 22a can be used as an external connection terminal that can be connected to, for example, wiring or an external component.

The third conductive member 23 is a plate-like member made of metal such as copper and is joined to the second semiconductor element 11B and the second diode 12B. The third conductive member 23 is joined to the upper surface 11Bb of the second semiconductor element 11B with a conductive joining material 116 and is joined to an upper surface 12Bb of the second diode 12B with a conductive joining material 126. A part of the third conductive member 23 which includes a joint portion between the second semiconductor element 11B and the second diode 12B is sealed with the sealing resin 30, together with the second semiconductor element 11B and the second diode 12B. The third conductive member 23 protrudes outward from the side surface 30a of the sealing resin 30 to form a protruding portion 23a. The protruding portion 23a can be used as an external connection terminal that can be connected to, for example, wiring or an external component.

A refrigerant pipe 50 through which an insulating refrigerant (to be also appropriately referred to as a “refrigerant” hereinafter) passes is provided for each of the first conductive member 21 and the third conductive member 23. As the insulating refrigerant, for example, a fluorine-based inert liquid or an insulating liquid such as oil can be used from the viewpoint of suppressing the occurrence of a short circuit. Hereinafter, the refrigerant pipe 50 provided in the first conductive member 21 is referred to as a “refrigerant pipe 50-1”, and the refrigerant pipe 50 provided in the third conductive member 23 is referred to as a “refrigerant pipe 50-3”. When the refrigerant pipe 50-1 and the refrigerant pipe 50-3 are not distinguished, they are collectively referred to as the “refrigerant pipe 50”. The refrigerant pipe 50 is an example of a cooling unit. The refrigerant pipe 50-1 is joined to the first conductive member 21 with a conductive joining material 113, and the refrigerant pipe 50-3 is joined to the third conductive member 23 with a conductive joining material 133. The first conductive member 21 is cooled by the refrigerant passing through the refrigerant pipe 50-1, and the third conductive member 23 is cooled by the refrigerant passing through the refrigerant pipe 50-3.

As described above, cooling the first conductive member 21 with the refrigerant in the refrigerant pipe 50 will cool the first semiconductor element 11A and the first diode 12A joined to the first conductive member 21. When the third conductive member 23 is cooled by the refrigerant in the refrigerant pipe 50, the second semiconductor element 11B and the second diode 12B joined to the third conductive member 23 are cooled. In the semiconductor device 1, the number of members located between the first semiconductor element 11A (second semiconductor element 11B) and the first diode 12A (second diode 12B) and the refrigerant in the refrigerant pipe 50 is smaller than that in a structure in which a semiconductor element, a circuit board, a base plate, and a cooling member are stacked. This promotes heat transfer from the first semiconductor element 11A, the first diode 12A, the second semiconductor element 11B, and the second diode 12B to the refrigerant. Therefore, according to the fifth embodiment, the heat generated in the first semiconductor element 11A, the first diode 12A, the second semiconductor element 11B, and the second diode 12B can be smoothly absorbed into the refrigerant. As a result, according to the fifth embodiment, the cooling efficiency of the first semiconductor element 11A, the first diode 12A, the second semiconductor element 11B, and the second diode 12B can be improved. In addition, since a part of the first conductive member 21 and a part of the third conductive member 23 are covered with the sealing resin 30, it is possible to suppress the first conductive member 21 and the third conductive member 23 from being directly exposed to the external environment. Therefore, according to the fifth embodiment, when the heat generated in the first semiconductor element 11A, the first diode 12A, the second semiconductor element 11B, and the second diode 12B is transferred to the refrigerant, a temperature rise of the refrigerant due to the external environment can be suppressed. As a result, according to the fifth embodiment, in the 2 in 1 semiconductor module, the cooling efficiency of the first semiconductor element 11A, the first diode 12A, the second semiconductor element 11B, and the second diode 12B can be improved.

The sixth embodiment relates to a variation of the cooling unit in the fourth embodiment.

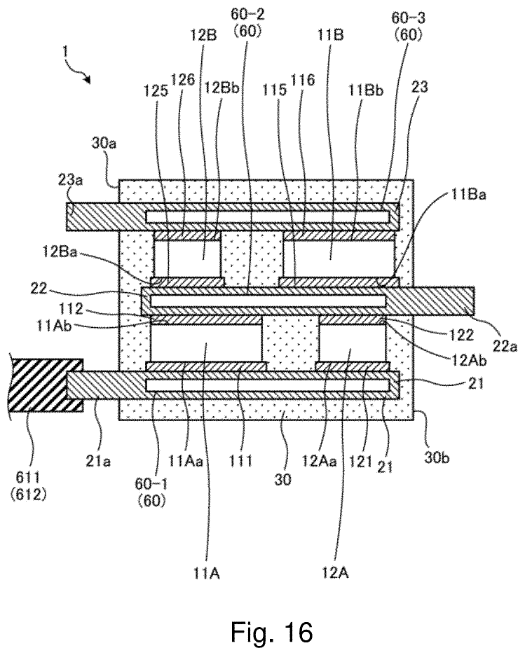

FIG. 16 is a schematic diagram illustrating a longitudinal cross-section of a semiconductor device 1 according to the sixth embodiment. As illustrated in FIG. 16, the semiconductor device 1 according to the sixth embodiment is a so-called 2 in 1 semiconductor module. The semiconductor device 1 includes a first semiconductor element 11A, a first diode 12A, a second semiconductor element 11B, and a second diode 12B. The semiconductor device 1 includes a first conductive member 21, a second conductive member 22, and a third conductive member 23. The first semiconductor element 11A, the first diode 12A, the second semiconductor element 11B, the second diode 12B, a part of the first conductive member 21, a part of the second conductive member 22, and a part of the third conductive member 23 are covered with a sealing resin 30. As the sealing resin 30, for example, an insulating resin such as an epoxy resin can be used.

In the following description, one surface side of the first semiconductor element 11A to which the first conductive member 21 is joined is defined as a lower side, and the other surface side of the first semiconductor element 11A to which the second conductive member 22 is joined is defined as an upper side. However, the semiconductor device 1 may be used, for example, upside down, or may be used in an arbitrary posture.

The first semiconductor element 11A and the second semiconductor element 11B are, for example, IGBTs. The first diode 12A and the second diode 12B are, for example, FWD. The combination of the first semiconductor element 11A and the first diode 12A and the combination of the second semiconductor element 11B and the second diode 12B are arranged at intervals in the vertical direction inside the sealing resin 30. Note that the first semiconductor element 11A and the second semiconductor element 11B may be power MOSFETs, GTO thyristors, or the like. Although the first diode 12A and the first semiconductor element 11A are distinguished here, the first diode 12A is also a type of semiconductor element. Although the second diode 12B and the second semiconductor element 11B are distinguished from each other, the second diode 12B is also a type of semiconductor element.

The first conductive member 21 is a plate-like member made of a metal such as copper and is joined to the first semiconductor element 11A and the first diode 12A. The first conductive member 21 is joined to a lower surface 11Aa of the first semiconductor element 11A with a conductive joining material 111 and is joined to a lower surface 12Aa of the first diode 12A with a conductive joining material 121. A part of the first conductive member 21 including a joint portion between the first semiconductor element 11A and the first diode 12A is sealed together with the first semiconductor element 11A and the first diode 12A with the sealing resin 30. The first conductive member 21 protrudes outward from one side surface 30a of the sealing resin 30 to form a protruding portion 21a. The protruding portion 21a can be used as an external connection terminal that can be connected to, for example, wiring or an external component.

The second conductive member 22 is a plate-like member made of a metal such as copper and is joined to the first semiconductor element 11A, the first diode 12A, the second semiconductor element 11B, and the second diode 12B. The second conductive member 22 is joined to an upper surface 11Ab of the first semiconductor element 11A with a conductive joining material 112 and is joined to the upper surface 12Ab of the first diode 12A with a conductive joining material 122. The second conductive member 22 is joined to a lower surface 11Ba of the second semiconductor element 11B with a conductive joining material 115 and is joined to a lower surface 12Ba of the second diode 12B with a conductive joining material 125. The first semiconductor element 11A, the first diode 12A, and a part of the second conductive member 22 which includes a joint portion between the second semiconductor element 11B and the second diode 12B are sealed with a sealing resin 30, together with the first semiconductor element 11A, the first diode 12A, the second semiconductor element 11B, and the second diode 12B. The second conductive member 22 protrudes outward from a side surface 30b opposite to the side surface 30a of the sealing resin 30 to form a protruding portion 22a. The protruding portion 22a can be used as an external connection terminal that can be connected to, for example, wiring or an external component.

The third conductive member 23 is a plate-like member made of metal such as copper and is joined to the second semiconductor element 11B and the second diode 12B. The third conductive member 23 is joined to the upper surface 11Bb of the second semiconductor element 11B with a conductive joining material 116 and is joined to an upper surface 12Bb of the second diode 12B with a conductive joining material 126. A part of the third conductive member 23 which includes a joint portion between the second semiconductor element 11B and the second diode 12B is sealed with the sealing resin 30, together with the second semiconductor element 11B and the second diode 12B. The third conductive member 23 protrudes outward from the side surface 30a of the sealing resin 30 to form a protruding portion 23a. The protruding portion 23a can be used as an external connection terminal that can be connected to, for example, wiring or an external component.

A through-hole 60 extending in the width direction of the first conductive member 21 is provided in a region overlapping the first semiconductor element 11A, the first diode 12A, the second semiconductor element 11B, and the second diode 12B in a plan view of each of the first conductive member 21, the second conductive member 22, and the third conductive member 23. Hereinafter, the through-hole 60 provided in the first conductive member 21 is referred to as a “through-hole 60-1”, the through-hole 60 provided in the second conductive member 22 is referred to as a “through-hole 60-2”, and the through-hole 60 provided in the third conductive member 23 is referred to as a “through-hole 60-3”. In addition, when the through-hole 60-1, the through-hole 60-2, and the through-hole 60-3 are not distinguished, they are collectively referred to as the “through-hole 60”.

One opening 61a (see FIG. 10) of the through-hole 60-1 serves as an inlet into which the refrigerant flows, and the other opening 61b (see FIG. 10) of the through-hole 60-1 serves as an outlet from which the refrigerant flows out. A refrigerant supply pipe 71 (see FIG. 10) that supplies a refrigerant to one opening 61a of the through-hole 60-1 is connected to one opening 61a of the through-hole 60-1. One opening 61a of the through-hole 60-1 is connected to the refrigerant supply pipe 71 by a known method such as solder joining, sintering, or laser processing. A refrigerant discharge pipe 72 (FIG. 10) for discharging the refrigerant from the other opening 61b of the through-hole 60-1 is connected to the other opening 61b of the through-hole 60-1. One opening 61b of the through-hole 60-1 is connected to the refrigerant discharge pipe 72 by a known method such as solder joining, sintering, or laser processing.

The refrigerant supply pipe 71 and the refrigerant discharge pipe 72 (see FIG. 10) protrude from one side surface 30a of the sealing resin 30. The refrigerant supply pipe 71 is connected to an inlet pipe 611 (see FIG. 10) formed of an insulating material, and the refrigerant discharge pipe 72 is connected to an outlet pipe 612 (see FIG. 10) formed of an insulating material. The inlet pipe 611 and the outlet pipe 612 are connected to a refrigerant circulation unit (not illustrated). The first conductive member 21 is cooled by circulating and supplying the refrigerant from the refrigerant circulation unit to the through-hole 60-1 through the inlet pipe 611, the refrigerant supply pipe 71, the refrigerant discharge pipe 72, and the outlet pipe 612. The refrigerant supply pipe 71 and the refrigerant discharge pipe 72 are examples of a cooling unit.

The configurations of the through-hole 60-2 provided in the second conductive member 22 and the through-hole 60-3 provided in the third conductive member 23 are basically similar to the configuration of the through-hole 60-1. Similarly to the through-hole 60-1, a refrigerant supply pipe and a refrigerant discharge pipe are connected to the through-hole 60-2, and the refrigerant supply pipe and the refrigerant discharge pipe are finally connected to the refrigerant circulation unit through an inlet pipe and an outlet pipe formed of an insulating material. The second conductive member 22 is cooled by circulating and supplying the refrigerant from the refrigerant circulation unit to the through-hole 60-2. In addition, similarly to the through-hole 60-1, a refrigerant supply pipe and a refrigerant discharge pipe are connected to the through-hole 60-3, and the refrigerant supply pipe and the refrigerant discharge pipe are finally connected to the refrigerant circulation unit through an inlet pipe and an outlet pipe formed of an insulating material. The third conductive member 23 is cooled by circulating and supplying the refrigerant from the refrigerant circulation unit to the through-hole 60-3.

As described above, cooling the first conductive member 21 and the second conductive member 22 with the refrigerant in the through-hole 60 will cool the first semiconductor element 11A and the first diode 12A joined to the first conductive member 21 and the second conductive member 22. Cooling the second conductive member 22 and the third conductive member 23 with the refrigerant in the through-hole 60 will cool the second semiconductor element 11B and the second diode 12B joined to the second conductive member 22 and the third conductive member 23. In the semiconductor device 1, the number of members located between the first semiconductor element 11A (second semiconductor element 11B) and the first diode 12A (second diode 12B) and the refrigerant in the through-hole 60 is smaller than that in a structure in which a semiconductor element, a circuit board, a base plate, and a cooling member are stacked. This promotes heat transfer from the first semiconductor element 11A, the first diode 12A, the second semiconductor element 11B, and the second diode 12B to the refrigerant. Therefore, according to the sixth embodiment, the heat generated in the first semiconductor element 11A, the first diode 12A, the second semiconductor element 11B, and the second diode 12B can be smoothly absorbed into the refrigerant. As a result, according to the sixth embodiment, the cooling efficiency of the first semiconductor element 11A, the first diode 12A, the second semiconductor element 11B, and the second diode 12B can be improved. In addition, since a part of the first conductive member 21, a part of the second conductive member 22, and a part of the third conductive member 23 are covered with the sealing resin 30, it is possible to suppress the first conductive member 21, the second conductive member 22, and the third conductive member 23 from being directly exposed to the external environment. Therefore, according to the sixth embodiment, when the heat generated in the first semiconductor element 11A, the first diode 12A, the second semiconductor element 11B, and the second diode 12B is transferred to the refrigerant, a temperature rise of the refrigerant due to the external environment can be suppressed. As a result, according to the sixth embodiment, in the 2 in 1 semiconductor module, the cooling efficiency of the first semiconductor element 11A, the first diode 12A, the second semiconductor element 11B, and the second diode 12B can be improved.

The first embodiment and the fourth embodiment described above each have exemplified the case in which the refrigerant passage 40 includes two openings (for example, openings 41a and 41b). However, the number of openings of the refrigerant passage 40 is not limited to two. That is, the refrigerant passage 40 may include two or more openings. In this case, at least one of the two or more openings of the refrigerant passage 40 may serve as a refrigerant inlet, and at least another opening may serve as a refrigerant outlet.

Furthermore, the above-described fourth to sixth embodiments each have exemplified the case in which the set of the first semiconductor element 11A and the first diode 12A and the set of the second semiconductor element 11B and the second diode 12B are arranged at intervals in the vertical direction. However, the disclosed technology is not limited to this. For example, a set of the first semiconductor element 11A and the first diode 12A and a set of the second semiconductor element 11B and the second diode 12B may be disposed at the same height position. In this case, an extending portion extending obliquely downward to the height position of the first conductive member 21 may be provided for the second conductive member 22, and the second semiconductor element 11B and the second diode 12B may be joined to the extending portion.

The semiconductor device 1 according to each of the above-described embodiments and modifications may be applied to, for example, a motor system mounted on a vehicle such as a hybrid vehicle or an electric vehicle.

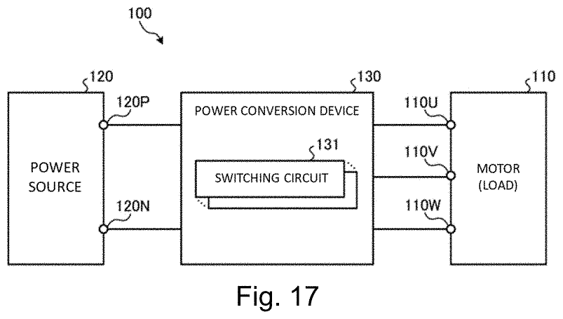

FIG. 17 is a diagram illustrating the configuration of a motor system 100 to which the semiconductor device 1 is applied. As illustrated in FIG. 17, the motor system 100 includes a motor 110, a power source 120, and a power conversion device 130.

The motor 110 is an example of a load. The motor 110 is a three-phase motor and has a U-phase terminal 110U, a V-phase terminal 110V, and a W-phase terminal 110W. Three-phase drive voltages that rotate the rotating shaft are applied to the U-phase terminal 110U, the V-phase terminal 110V, and the W-phase terminal 110W of the motor 110.

The power source 120 generates DC power. The power source 120 has a positive terminal 120P and a negative terminal 120N. The power source 120 outputs a positive power source voltage from the positive terminal 120P. The power source 120 outputs a negative power source voltage or 0 V from the negative terminal 120N.

The power conversion device 130 receives DC power from the power source 120, performs power conversion, and supplies AC power to the motor 110 as a load. That is, the power conversion device 130 converts the DC power received from the power source 120 into three-phase AC power and supplies the three-phase AC voltage to the motor 110.

In addition, a plurality of switching circuits 131 each configured to perform a switching operation for converting DC power into AC power are mounted inside the power conversion device 130. The semiconductor device 1 according to each of the above-described embodiments and modifications can be applied to the switching circuit 131. That is, the power conversion device 130 may include the semiconductor device 1 as the switching circuit 131.

Note that the power conversion device 130 is not limited to the motor 110 and may supply power to any load. For example, the power conversion device 130 may supply power to a motor other than the three-phase motor.

As described above, the semiconductor device (for example, the semiconductor device 1) according to the embodiment includes the semiconductor element (for example, the semiconductor element 11, the first semiconductor element 11A, and the second semiconductor element 11B), the conductive member (for example, the first conductive member 21, the second conductive member 22, and the third conductive member 23), the resin (for example, the sealing resin 30), and the cooling unit. The conductive member is joined to the semiconductor element. The resin seals a part of the semiconductor element and the conductive member. The cooling unit cools the conductive member inside the resin. This enables the semiconductor device according to the embodiment to improve the cooling efficiency of the semiconductor element. In addition, according to the semiconductor device of the embodiment, since the semiconductor element can be cooled with high efficiency, the operation of the semiconductor element can be stabilized, the life of the semiconductor element can be prolonged, and the power efficiency of the semiconductor element can be improved. In addition, according to the semiconductor device according to the embodiment, since the number of members can be reduced as compared with a structure in which a semiconductor element, a circuit board, a base plate, and a cooling member are stacked, the semiconductor device can be downsized.

The cooling unit may be a refrigerant passage (for example, the refrigerant passage 40) that is provided inside the conductive member and allows the insulating refrigerant to pass therethrough. This enables the semiconductor device according to the embodiment to improve the cooling efficiency of the semiconductor element.

The conductive member may have protruding portions (for example, the protruding portions 21a, 22a, and 23a) protruding from one side surface (for example, the side surface 30a or 30b) of the resin. The refrigerant passage may include two or more openings (for example, the openings 41a and 41b, the openings 42a and 42b, and the openings 43a and 43b), and two or more openings may be disposed in the protruding portion. This allows the semiconductor device according to the embodiment to concentrate the inlet and the outlet of the refrigerant on one side surface side of the sealing resin. Accordingly, the semiconductor device can be downsized.

The conductive member may have a first protruding portion (for example, the protruding portion 21a) protruding from one side surface (for example, the side surface 30a) of the resin and a second protruding portion (for example, the protruding portion 21b) protruding from another side surface (for example, the side surface 30c) of the resin. The refrigerant passage may include two openings. One of the two openings (for example, the opening 41a) may be disposed in the first protruding portion, and the other opening (for example, the opening 41b) may be disposed in the second protruding portion. As a result, according to the semiconductor device according to the embodiment, the inlet and the outlet of the refrigerant are dispersed on the two side surfaces of the sealing resin, and the degree of freedom of the circulation path of the refrigerant can be improved.

The semiconductor device according to the embodiment may include a plurality of conductive members. The plurality of conductive members may include the first conductive member (for example, the first conductive member 21) joined to the first surface (for example, the lower surface 11a or 11Aa) of the semiconductor element and the second conductive member (for example, the second conductive member 22) joined to the second surface (for example, the upper surface 11b or 11Ab) opposite to the first surface of the semiconductor element. The refrigerant passage may be provided inside at least one of the first conductive member and the second conductive member. As a result, according to the semiconductor device according to the embodiment, it is possible to highly efficiently cool the semiconductor element from both surfaces or one surface side of the semiconductor element to which the first conductive member and the second conductive member are joined.

The semiconductor device according to the embodiment may include a plurality of semiconductor elements and a plurality of conductive members. The plurality of semiconductor elements may include the first semiconductor element (for example, the first semiconductor element 11A) and the second semiconductor element (for example, the second semiconductor element 11B). The plurality of conductive members may include the first conductive member (for example, the first conductive member 21) joined to the first surface (for example, the lower surface 11Aa) of the first semiconductor element, the second conductive member (for example, the second conductive member 22) joined to the second surface (for example, the upper surface 11Ab) opposite to the first surface of the first semiconductor element and joined to the first surface (for example, the lower surface 11Ba) of the second semiconductor element, and the third conductive member (for example, the third conductive member 23) joined to the second surface (for example, the upper surface 11Bb) opposite to the first surface of the second semiconductor element. The refrigerant passage may be provided inside at least one of the first conductive member, the second conductive member and the third conductive member. As a result, according to the semiconductor device according to the embodiment, it is possible to highly efficiently cool the first semiconductor element from both surfaces or one surface side of the first semiconductor element to which the first conductive member and the second conductive member are joined. In addition, according to the semiconductor device according to the embodiment, it is possible to highly efficiently cool the second semiconductor element from both surfaces or one surface side of the second semiconductor element to which the second conductive member and the third conductive member are joined. That is, according to the semiconductor device according to the embodiment, the cooling efficiency of the first semiconductor element and the second semiconductor element can be improved in the 2-in-1 semiconductor module.

The cooling unit may be a refrigerant pipe (for example, the refrigerant pipe 50) that is joined to the conductive member and allows the insulating refrigerant to pass therethrough. This enables the semiconductor device according to the embodiment to improve the cooling efficiency of the semiconductor element.

Both ends (for example, the end portions 51a and 51b and the end portions 52a and 52b) of the refrigerant pipe may protrude from one side surface (for example, the side surface 30a or 30b) of the resin. This allows the semiconductor device according to the embodiment to concentrate the inlet and the outlet of the refrigerant on one side surface side of the sealing resin. Accordingly, the semiconductor device can be downsized.

One end (For example, the end portion 51a) of the refrigerant pipe may protrude from one side surface (For example, the side surface 30a) of the resin, and the other end (for example, the end portion 51b) may protrude from the other side surface (for example, the side surface 30c) of the resin. As a result, according to the semiconductor device according to the embodiment, the inlet and the outlet of the refrigerant are dispersed on the two side surfaces of the sealing resin, and the degree of freedom of the circulation path of the refrigerant can be improved.

The semiconductor device according to the embodiment may include a plurality of conductive members. The plurality of conductive members may include the first conductive member joined to the first surface of the semiconductor element and the second conductive member joined to the second surface of the semiconductor element on a side opposite to the first surface. The refrigerant pipe may be provided for at least one of the first conductive member and the second conductive member. As a result, according to the semiconductor device according to the embodiment, it is possible to highly efficiently cool the semiconductor element from both surfaces or one surface side of the semiconductor element to which the first conductive member and the second conductive member are joined.

The semiconductor device according to the embodiment may include a plurality of semiconductor elements and a plurality of conductive members. The plurality of semiconductor elements may include the first semiconductor element and the second semiconductor element. The plurality of conductive members may include the first conductive member joined to the first surface of the first semiconductor element, the second conductive member joined to the second surface opposite to the first surface of the first semiconductor element and joined to the first surface of the second semiconductor element, and the third conductive member joined to the second surface opposite to the first surface of the second semiconductor element. The refrigerant pipe may be provided for each of the first conductive member and the third conductive member. As a result, according to the semiconductor device according to the embodiment, the first semiconductor element can be cooled with high efficiency from one surface side of the first semiconductor element to which the first conductive member is joined. In addition, according to the semiconductor device according to the embodiment, the second semiconductor element can be cooled with high efficiency from one surface side of the second semiconductor element to which the third conductive member is joined. That is, according to the semiconductor device according to the embodiment, the cooling efficiency of the first semiconductor element and the second semiconductor element can be improved in the 2-in-1 semiconductor module.

The conductive member may have a through-hole (for example, the through-hole 60) formed in a region overlapping the semiconductor element in plan view and extending in the width direction of the conductive member. The cooling unit may include a refrigerant supply pipe (for example, the refrigerant supply pipe 71) that supplies the insulating refrigerant to one opening (for example, the opening 61a) of the through-hole and a refrigerant discharge pipe (for example, the refrigerant discharge pipe 72) that discharges the insulating refrigerant from the other opening (for example, the opening 61b) of the through-hole. This enables the semiconductor device according to the embodiment to improve the cooling efficiency of the semiconductor element.

The conductive member may have a plurality of through-holes. The refrigerant supply pipe may supply the insulating refrigerant to one opening of each through-hole. The refrigerant discharge pipe may discharge the insulating refrigerant from the other opening of each through-hole. As a result, according to the semiconductor device according to the embodiment, since the contact area between the conductive member and the refrigerant can be increased, the cooling efficiency of the semiconductor element can be further improved.

The semiconductor device according to the embodiment may include a plurality of semiconductor elements and a plurality of conductive members. The plurality of semiconductor elements may include the first semiconductor element and the second semiconductor element. The plurality of conductive members may include the first conductive member joined to the first surface of the first semiconductor element, the second conductive member joined to the second surface opposite to the first surface of the first semiconductor element and joined to the first surface of the second semiconductor element, and the third conductive member joined to the second surface opposite to the first surface of the second semiconductor element. The through-hole may be formed in at least one of the first conductive member, the second conductive member and the third conductive member. As a result, according to the semiconductor device according to the embodiment, it is possible to highly efficiently cool the first semiconductor element from both surfaces or one surface side of the first semiconductor element to which the first conductive member and the second conductive member are joined. In addition, according to the semiconductor device according to the embodiment, it is possible to highly efficiently cool the second semiconductor element from both surfaces or one surface side of the second semiconductor element to which the second conductive member and the third conductive member are joined. That is, according to the semiconductor device according to the embodiment, the cooling efficiency of the first semiconductor element and the second semiconductor element can be improved in the 2-in-1 semiconductor module.

The semiconductor element may be an insulated gate bipolar transistor. Thus, according to the semiconductor device of the embodiment, the cooling efficiency of the insulated gate bipolar transistor can be improved.

The material of the semiconductor element may be silicon, silicon carbide, or gallium nitride.

The power conversion device (for example, the power conversion device 130) according to the embodiment may include a semiconductor device (for example, the semiconductor device 1). This enables the power conversion device according to the embodiment to improve the cooling efficiency of the semiconductor element.

The embodiments disclosed in this case should be considered as an example in all points and not restrictive. Indeed, the embodiments described above may be embodied in various forms. The above embodiments allow omissions, replacements, and changes in various forms without departing from the scope and spirit of the appended claims.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A semiconductor device comprising:
a semiconductor element;
a conductive member joined to the semiconductor element;
a resin that seals a part of the semiconductor element and the conductive member; and
a cooling unit that cools the conductive member inside the resin.

2. The semiconductor device according to claim 1, wherein the cooling unit is a refrigerant passage that is provided inside the conductive member and allows an insulating refrigerant to pass therethrough.

3. The semiconductor device according to claim 2, wherein
the conductive member has a protruding portion protruding from one side surface of the resin,
the refrigerant passage includes not less than two openings, and
not less than the two openings are disposed in the protruding portion.

4. The semiconductor device according to claim 2, wherein
the conductive member includes a first protruding portion protruding from one side surface of the resin and a second protruding portion protruding from another side surface of the resin, and
the refrigerant passage includes two openings, with one of the two openings being disposed in the first protruding portion and the other opening being disposed in the second protruding portion.

5. The semiconductor device according to claim 2, further comprising a plurality of the conductive members,
the plurality of conductive members including a first conductive member joined to a first surface of the semiconductor element and a second conductive member joined to a second surface opposite to the first surface of the semiconductor element, wherein
the refrigerant passage is provided inside at least one of the first conductive member and the second conductive member.

6. The semiconductor device according to claim 2, further comprising a plurality of the semiconductor elements and a plurality of the conductive members,
the plurality of semiconductor elements including a first semiconductor element and a second semiconductor element and the plurality of conductive members including a first conductive member joined to a first surface of the first semiconductor element, a second conductive member joined to a second surface opposite to the first surface of the first semiconductor element and joined to the first surface of the second semiconductor element, and a third conductive member joined to a second surface opposite to the first surface of the second semiconductor element, wherein
the refrigerant passage is provided inside at least one of the first conductive member, the second conductive member and the third conductive member.

7. The semiconductor device according to claim 1, wherein the cooling unit is a refrigerant pipe that is joined to the conductive member and allows an insulating refrigerant to pass therethrough.

8. The semiconductor device according to claim 7, wherein the refrigerant pipe has both ends protruding from one side surface of the resin.

9. The semiconductor device according to claim 7, wherein the refrigerant pipe has one end protruding from one side surface of the resin and the other end protruding from another side surface of the resin.

10. The semiconductor device according to claim 7, further comprising a plurality of the conductive members,
the plurality of conductive members including a first conductive member joined to a first surface of the semiconductor element and a second conductive member joined to a second surface opposite to the first surface of the semiconductor element, wherein
the refrigerant pipe is provided on at least one of the first conductive member and the second conductive member.

11. The semiconductor device according to claim 7, further comprising a plurality of the semiconductor elements and a plurality of the conductive members,
the plurality of semiconductor elements including a first semiconductor element and a second semiconductor element and the plurality of conductive members including a first conductive member joined to a first surface of the first semiconductor element, a second conductive member joined to a second surface opposite to the first surface of the first semiconductor element and joined to the first surface of the second semiconductor element, and a third conductive member joined to a second surface opposite to the first surface of the second semiconductor element, wherein
the refrigerant pipe is provided inside each of the first conductive member and the third conductive member.

12. The semiconductor device according to claim 1, wherein
the conductive member has a through-hole formed in a region overlapping the semiconductor element in plan view and extending in a width direction of the conductive member, and
the cooling unit includes a refrigerant supply pipe that supplies an insulating refrigerant to one opening of the through-hole and a refrigerant discharge pipe that discharges an insulating refrigerant from the other opening of the through-hole.

13. The semiconductor device according to claim 12, wherein
the conductive member has a plurality of the through-holes,
the refrigerant supply pipe supplies an insulating refrigerant to one opening of each of the through-holes, and
the refrigerant discharge pipe discharges the insulating refrigerant from the other opening of each of the through-holes.

14. The semiconductor device according to claim 12, further comprising a plurality of the semiconductor elements and a plurality of the conductive members,
the plurality of semiconductor elements including a first semiconductor element and a second semiconductor element and the plurality of conductive members including a first conductive member joined to a first surface of the first semiconductor element, a second conductive member joined to a second surface opposite to the first surface of the first semiconductor element and joined to the first surface of the second semiconductor element, and a third conductive member joined to a second surface opposite to the first surface of the second semiconductor element, wherein
the through-hole is provided in at least one of the first conductive member, the second conductive member and the third conductive member.

15. The semiconductor device according to claim 1, wherein the semiconductor element is an insulated gate bipolar transistor or a power MOSFET.

16. A power conversion device comprising the semiconductor device according to claim 1.
